(19) United States
(12) Patent Application Publication
(10) Pub. No.: US 2024/0402225 A1
(43) Pub. Date: Dec. 5, 2024

(54) DEVICE FOR CHECKING SURGE

(71) Applicant: Checkmain Inc., Bucheon-si (KR)

(72) Inventor: Byung Jun KIM, Bucheon-si (KR)

(73) Assignee: Checkmain Inc., Bucheon-si (KR)

(21) Appl. No.: 18/680,647

(22) Filed: May 31, 2024

(30) Foreign Application Priority Data
May 31, 2023 (KR) 10-2023-0070142

(51) Int. Cl. G01R 19/165; H01F 7/06; H01F 7/08

(52) U.S. Cl. CPC G01R 19/16571; H01F 7/064; H01F 7/081

(57) ABSTRACT

A device for checking a surge to sense a surge of a target conducting wire according to an embodiment of the present disclosure may include: an electromotive force generator that is formed to surround at least a portion of the target conducting wire at a predetermined distance from the target conducting wire and generates an electromotive force on the basis of a surge current generated in the target conducting wire; and a notification unit that includes a solenoid and a core formed at a center in the solenoid and notifies of generation of a surge on the basis of movement of the core when power is supplied to the solenoid with generation of the electromotive force.

### CROSS-REFERENCE TO RELATED APPLICATION(S)

This application claims the benefit under 35 USC 119 (a) of Korean Patent Application No. 10-2023-0070142, filed with the Korean Intellectual Property Office on May 31, 2023, the disclosure of which is incorporated herein by reference in its entirety.

### TECHNICAL FIELD

The present disclosure relates to a device for checking a surge. In more detail, the present disclosure relates to a device for checking occurrence of a surge event due to a thunderbolt, etc. and notifying of occurrence of the surge event.

### BACKGROUND

Since most electric devices, electronic circuits, communication devices, etc. that are recently used use low-power large scale integrated circuits, they may be fatally damaged even by a low surge voltage.

Accordingly, many products equipped with a surge protection device (SPD) that can effectively protect internal circuits from a surge voltage are being introduced. However, the lifespan of such surge protection devices depends on the number of times of inflow of surges, the capacity/magnitude of surges, or the like. Accordingly, it is required to check the number of times of inflow of surges into a surge protection device in order to check the lifespan of the surge protection device and replace the surge protection device at the right time.

Further, when a surge protection device does not normally operate, a surge may flow into the facility that is protected by the surge protection device. In this case, it is also required to check whether there is a surge flowing into the facility and the number of times of inflow of surges and it is possible to check whether the surge protection device connected to the facility normally operates by checking surges flowing into the facilities.

In addition, it is required to check inflow of a surge in other situations, and accordingly, there is a need for measures to give support so that it is possible to effectively check inflow of surges and manage surges.

### PRIOR ART DOCUMENT

### Patent Document

Korean Patent No. 10-0938460 (Portable apparatus for inspecting surge protector)

### SUMMARY

The present disclosure has been designed to check generation of a surge in a conducting wire and notify a user of generation of the surge.

The present disclosure has been designed to check a surge flowing in a target conducting wire without damaging the target conducting wire.

The present disclosure has been designed to perform operation of notifying of generation of a surge using an electromotive force generated by a surge generated in a target conducting wire.

The objectives of the present disclosure are not limited to those described above and other objectives and advantages not stated herein may be understood through the following description and may be clear by embodiments of the present disclosure. Further, it would be easily known that the objectives and advantages of the present disclosure may be achieved by the configurations described in claims and combinations thereof.

A device for checking a surge to sense a surge of a target conducting wire according to an embodiment of the present disclosure may include: an electromotive force generator that is formed to surround at least a portion of the target conducting wire at a predetermined distance from the target conducting wire and generates an electromotive force on the basis of a surge current generated in the target conducting wire; and a notification unit that includes a solenoid and a core formed at a center in the solenoid and notifies of generation of a surge on the basis of movement of the core when power is supplied to the solenoid with generation of the electromotive force.

Further, the device for checking a surge may further include a switch unit that includes an additional power supplier and controls the additional power supplier to supply power of a preset capacity to the solenoid when a surge current is generated in the target conducting wire and an electromotive force is correspondingly generated.

Further, the device for checking a surge may further include a main body housing that accommodates the electromotive force generator and the notification unit.

Further, the notification unit includes a button member that is operated with the core formed at the center in the solenoid in contact with an end of the core, and when power is supplied to the solenoid, the core formed at the center in the solenoid protrudes and can push the button member out of the main body housing.

Further, the electromotive force generator may be configured in a type in which a pair of U-shaped structures is fixed in a contact state to form an O-shaped hole at the center.

In this case, the U-shaped structures may be ferrite cores.

Further, the electromotive force generator is composed of an upper part that is a structure positioned at the upper end and a lower part that is a structure positioned at the lower end in the contact state for forming an O-shaped hole, the upper part and the lower part are connected through a hinge, and the opening/closing state can be determined in correspondence to movement of the hinge.

Further, the device for checking a surge may further include a communication unit that transmits information of generation of a surge to an external server when a circuit is connected to a power source.

Further, when power is supplied to the solenoid with generation of the electromotive force and the core is moved, the notification unit can connect the circuit of the communication unit in correspondence to movement of the core.

A device for sensing a surge of a target conducting wire according to various embodiments of the present disclosure may include an electromotive force generator that is formed to surround at least a portion of the target conducting wire at a predetermined distance from the target conducting wire and generates an electromotive force on the basis of a surge current generated in the target conducting wire, and a notification unit that includes at least one light emission element and notifies of generation of a surge by driving the light emission element on the basis of the generated electromotive force.

The present disclosure can check occurrence of a surge in a conducting wire and can notify a user of occurrence of the surge in a simple way.

The present disclosure can check a surge flowing in a target conducting wire without damaging the target conducting wire.

The present disclosure can perform operation of notifying of occurrence of a surge using an electromotive force generated by a surge generated in a target conducting wire.

### BRIEF DESCRIPTION OF THE DRAWINGS

FIG. 1 is a view simply showing the structure of a device for checking a surge according to an embodiment of the present disclosure.

FIG. 2 is a view showing the external appearance of the device for checking a surge according to an embodiment of the present disclosure.

FIG. 3 is a view showing the internal structure of the device for checking a surge according to an embodiment of the present disclosure.

FIG. 4 is a view showing the internal structure of the device for checking a surge according to an embodiment of the present disclosure.

FIG. 5 is a view illustrating an electromotive force generator included in a device for checking a surge according to an embodiment of the present disclosure.

FIG. 6 is diagram illustrating the operation method of a device for checking a surge according to another embodiment of the present disclosure.

FIG. 7 is diagram illustrating a notification unit of a device for checking a surge according to an embodiment of the present disclosure.

FIG. 8 is a view showing the structure of a device for checking a surge that includes at least one light emission element in accordance with an embodiment of the present disclosure.

FIG. 9 is a view illustrating the opening/closing types of an electromotive force generator according to an embodiment of the present disclosure.

FIG. 10 is diagram illustrating an extension method of a device for checking a surge according to an embodiment of the present disclosure.

FIG. 11 is a block diagram showing the configuration of a device for checking a surge according to an embodiment of the present disclosure.

### DETAILED DESCRIPTION

The advantages and features of the present disclosure, and methods of achieving them will be clear by referring to the embodiments that will be describe below in detail with reference to the accompanying drawings. However, the present disclosure is not limited to the exemplary embodiments described hereafter and may be implemented in various ways, and the exemplary embodiments are provided to complete the description of the present disclosure and let those skilled in the art completely know the scope of the present disclosure and the present disclosure is defined by claims.

The terms used herein are provided to describe embodiments without limiting the present disclosure. In the specification, a singular form includes a plural form unless specifically stated in the sentences. The terms “comprise” and/or “comprising” used herein do not exclude that another component exists or is added other than the stated component. Throughout the specification, the same reference numerals indicate the same components, and the term “and/or” includes each of the stated components and all of one or more combinations. Although terms “first”, “second”, etc. are used to describe various components, it should be noted that these components are not limited by the terms. These terms are used only for discriminating a component from another component. Accordingly, it should be noted that a first component that is stated below may be a second component within the spirit of the present disclosure.

Unless defined otherwise, all terms (including technological and scientific terminologies) used herein may be used as meanings that those skilled in the art can commonly understand. Further, terms defined in common dictionaries are not construed ideally or excessively unless specifically clearly defined.

Further, the term “unit” or “module” used herein means a software component or a hardware component such FPGA, or ASIC and performs predetermined functions. However, the term “unit” or “module” is not limited to software or hardware. A “unit” and a “module” may be configured to be stored in a storage medium that can be addressed or may be configured to regenerate one or more processors. Accordingly, for example, the “unit” or “module” includes components such as software components, object-oriented software components, class components, and task components, processors, functions, properties, procedures, subroutines, segments of a program code, drivers, firmware, a microcode, a circuit, data, a database, data structures, tables, arrays, and variables. Functions provided by the components and the “unit” or “module” may be combined in a smaller number of components and “unit” or “module” or may be further separated into additional components and “unit” or “module”

Spatial relative terms “below”, “beneath”, “lower”, “above”, “upper”, etc. may be used to easily describe the correlation of one component and another component, as shown in the drawings. The spatially relative terms should be construed as terminologies including different directions of components in using or in operating in addition to the directions shown in drawings. For example, when components shown in the drawings are turned upside down, a component described as being “below” or “beneath” another component may be positioned “above” the another component. Accordingly, “below” and “beneath” that are exemplary terms may include both of up and down directions. A component may be oriented in different directions, so the spatially relative terms may be construed in accordance with orientation.

Hereinafter, embodiments of the present disclosure are described with reference to the accompanying drawings.

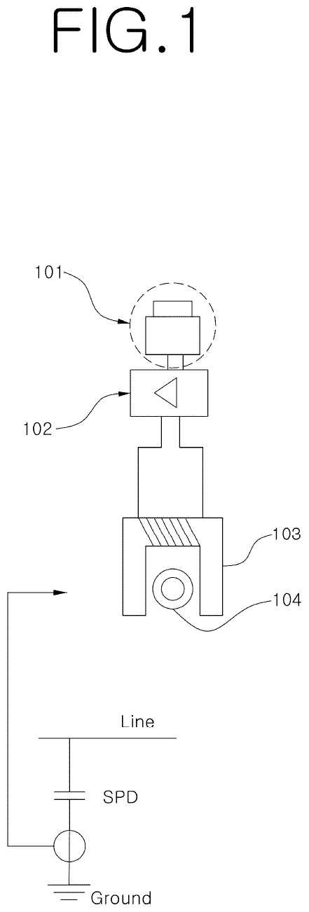

FIG. 1 is a view simply showing the structure of a device for checking a surge according to an embodiment of the present disclosure.

As shown in FIG. 1, a device for checking a surge according to an embodiment of the present disclosure may be installed to sense a surge that flows through a ground wire by a surge protection device (PSD), etc. Accordingly, the device for checking a surge can check whether the surge protection device normally operates.

However, the device for checking a surge is not limited thereto and may be used to check lighting strikes to power transmission and distribution facilities and operation of a lighting arrester.

Further, according to that shown in FIG. 1, the device for checking a surge may include an electromotive force generator 103 surrounding a target conducting wire 104 (e.g., a ground wire). Further, the electromotive force generator 103 may be configured as a ferrite core in accordance with an embodiment. Accordingly, the electromotive force generator 103 is formed by winding a coil on a material having magnetism, and can generate an electromotive force according to the principle of electromagnetic induction when a surge is generated in a target conducting wire.

The electromotive force generated by the electromotive force generator 103 can be transmitted to a notification unit 101 through a circuit 102. In this case, the notification unit 101 can perform a function of notifying of generation of a surge through a protruding operation of a button.

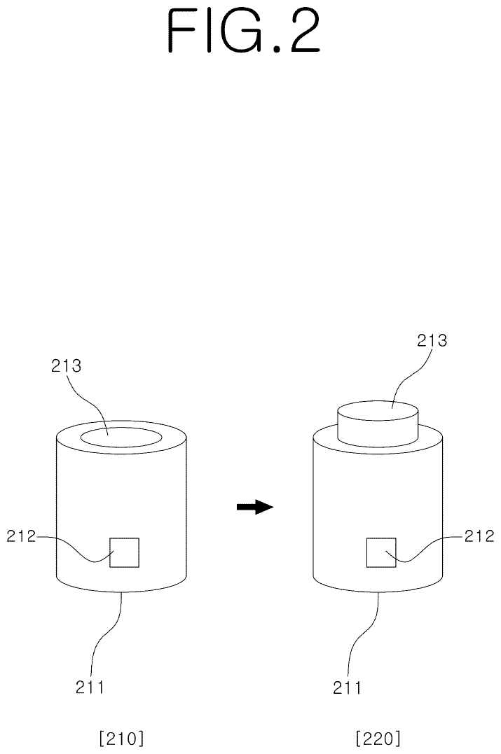

The external appearance of the device for checking a surge is as shown in FIG. 2.

As shown in FIG. 2, the device for checking a surge is in the state in which the button of the notification unit has not protruded as in [210] when a surge event is not sensed, but may be in the state in which the button of the notification unit has protruded as in [220] when a surge event is sensed. Further, the device for checking a surge may include a housing 211 that accommodates the electromotive force generator and the notification unit described above, and a hole 212 through which a conducting wire that is the target of sensing can pass may be formed at the lower end portion of the housing. The hole 212 may be provided in correspondence to the position of a hole formed by the electromotive force generator. Accordingly, a target conducting wire is installed through the hole of the housing and the hole formed by the electromotive force generator, and in this state, the device for checking a surge can sense a surge flowing in the target conductive wire.

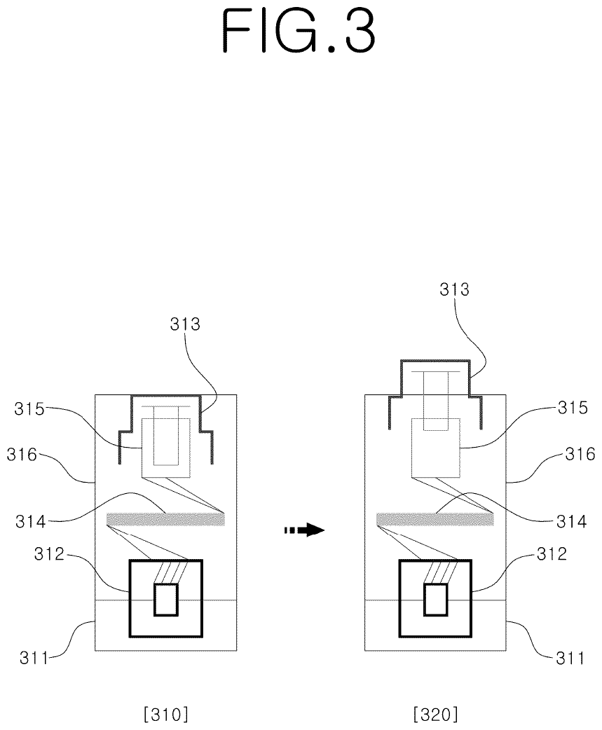

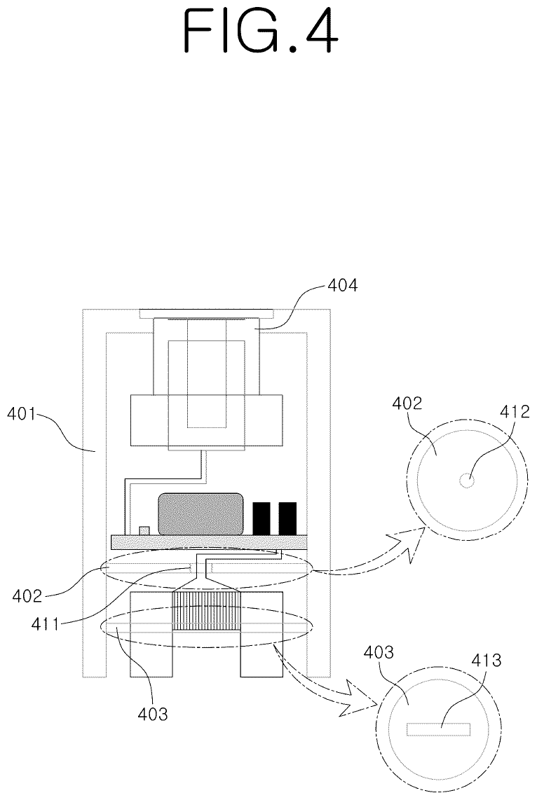

FIGS. 3 to 4 are referred to in order to describe in more detail the configuration of the device for checking a surge.

The device for checking a surge according to an embodiment may include a solenoid in a notification unit. In this case, the notification unit can perform operation of notifying generation of a surge in accordance with operation of the solenoid.

In detail, the device for checking a surge includes an electromotive force generator 312 and the electromotive force generator 312 is formed to surround at least a portion of a target conducting wire at a predetermined distance from the target conducting wire and can generate an electromotive force on the basis of a surge current generated in the target conducting wire. Further, the electromotive force generated by the electromotive force generator 312 can be transmitted to a solenoid 315 of a notification unit through a circuit 314.

The electromotive force generator 312 may be a ferrite core on which a coil is wound ten times in accordance with an embodiment. However, the electromotive force generator 312 is not limited thereto and the number of times of winding a coil on the electromotive force generator 312 may be increased or decreased. The electromotive force generator 312 may be implemented in an O-shape by bringing two U-shaped structures together to generate an electromotive force in correspondence to a target conducting wire in which a surge has been generated. Further, a coil may be wound only on a main body of the electromotive force generator 312. In this case, the main body of the electromotive force generator 312 on which a coil is wound may mean, as shown in FIG. 3, an upper end (an upper end and a lower end) excluding sides on the basis of the hole in which a target conducting wire is positioned.

The notification unit may include a solenoid 315, a core (and a button member (an iron core) disposed at the center in the solenoid, and a button member positioned in contact with an end of the core and operating with movement of the core. According to the notification unit, when power is supplied to the solenoid, the core formed at the center in the solenoid protrudes and can push the button member 313 out of a main body housing 316. Accordingly, when a surge is sensed, the notification unit can notify of generation of the surge in a way of protruding the button.

Further, a lower end cover 311 that fixes the lower end portion of the electromotive force generator 312 may be disposed at the lower end of the main body housing 316. The lower end cover 311 can be moved together with the lower end portion of the electromotive force generator 312 and can be detachably attached to the main body housing.

Further, as shown in FIG. 4, the device for checking a surge may include a plurality of diaphragms disposed in the main body housing 401. The diaphragms may include a wire hole diaphragm 402 having a wire hole 412 through which a wire, through which an electromotive force generated by the electromotive force generator moves, passes, and a core hole diaphragm 403 having a hole 413 for fixing the electromotive force generator. The space between the wire hole 421 and a wire may be waterproofed with silicon/resin, etc.

Further, FIG. 4 shows an example in which a switch unit is installed in addition to an electromotive force generator and a notification unit. The switch unit may include an additional power supplier (e.g., a battery), and when a surge current is generated in the target conducting wire and an electromotive force is correspondingly generated, the switch unit can control the additional power supplier to supply power of a preset capacity to the solenoid. This is a method for using additional external power because the capacity of an electromotive force generated with sensing of a surge current may be insufficient as power for operating the solenoid. Accordingly, in this case, the electromotive force generator has only to supply an electromotive force that is such that a sensor of the switch unit can sense generation of a surge. Further, when an electromotive force is supplied from the electromotive force generator, the switch unit can recognize the electromotive force, change additional external power (battery) into an ON state, and control the additional external power to supply power enough to operate the solenoid of the notification unit.

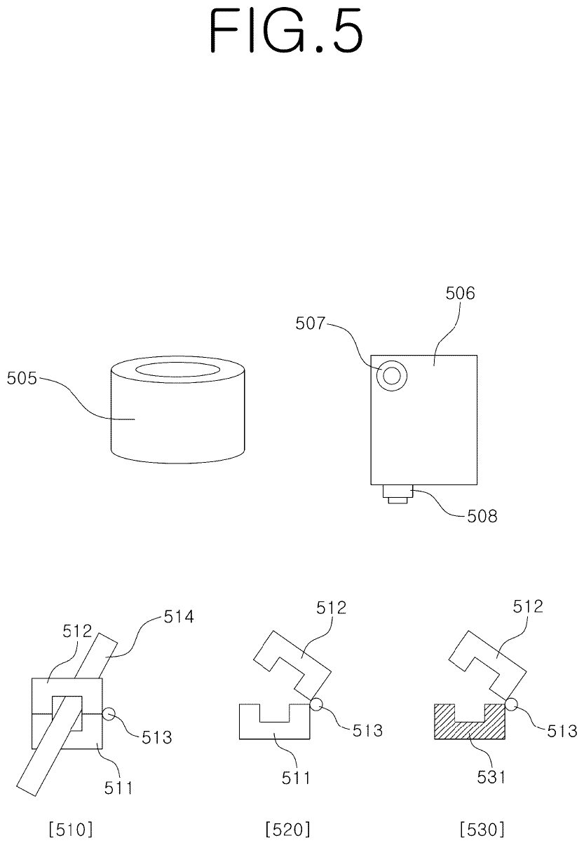

Further, as shown in FIG. 5, in the device for checking a surge according to an embodiment of the present disclosure, an electromotive force generator 505 may be installed to extend out of the main body to be able to check the inside of the main body housing without performing movements such as opening the main body housing and the lower end cover in order to see the inside of the main body housing. “507” shows the state in which an electromotive force generator has been installed to extend from a region of the front of the main body housing 506 and “508” shows the state in which an electromotive force generator has been installed to extend from the lower end of the main body housing.

Further, the electromotive force generator, as shown in [510], may be formed by fixing two U-shaped structures in contact with each other to have a hole at the center in a shape surrounding a target conducting wire 514. In this case, the two U-shaped structures (ferrite cores) may be connected through a hinge 513 and may include an upper part 512 positioned at the upper end from the hinge position and a lower part 511 positioned at the lower end from the hinge position.

Further, the electromotive force generator, as shown in [520], can be opened/closed in accordance with movement of the hinge 513. Accordingly, a target conducting wire can be inserted into the center of the electromotive force generator when the two contact U-shaped structures are opened. [530] shows an example in which the structure positioned at the lower end of U-shaped structures constituting the electromotive force generator is a common fixed case rather than a ferrite core. In this case, the surge sensitivity is deteriorated in comparison to the example in which the upper part 512 and the lower part 511 are both ferrite cores. The electromotive force generator can adjust sensitivity in accordance with the capacity of a surge expected to flow into a target conducting wire.

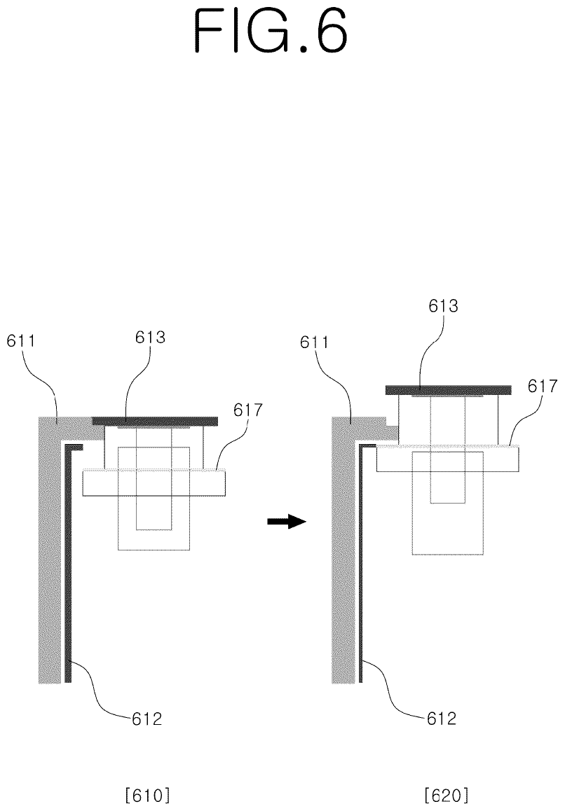

Further, FIG. 6 shows an example in which a device for checking a surge according to an embodiment of the present disclosure performs communication operation in correspondence to operation of a notification unit.

According to another embodiment, the device for checking a surge according to various embodiments may include a communication unit that performs communication operation with an external server. Further, as shown in [610], when a surge event is not sensed, there no current flowing into the solenoid, and the notification unit does not protrude, circuits 617 and 612 are disconnected, so the communication unit may not be operated. However, as shown in [620], when power is supplied to the solenoid due to generation of a surge and the notification unit correspondingly protrudes, the circuits 617 and 612 are connected, so the communication unit can be operated.

As described above, the device for checking a surge changes the communication unit into an OFF state through operation of the notification unit (a solenoid and a solenoid core) before a surge event occurs, and when a surge event occurs, the device for checking a surge operates also the communication unit in accordance with operation of the notification unit, so it is possible to reduce consumption of standby power that is applied to the communication unit.

The communication unit is connected with a circuit, so when it is turned on, it can transmit surge event information to an external server. Accordingly, the external server can obtain and record information of a surge event such as the number of times of generation of the surge.

The communication unit consumes standby power until the notification that has protruded returns and the connection state of the circuit is changed into an OFF state, and a user can change the connection state of the communication unit circuit into an OFF state by pressing the button member of the notification unit.

Further, a reflective part 613 that protrudes with the button member of the notification unit may be installed at the upper end of the button member. The reflective part 613 can make it possible to easily visually check a protruding state using a reflective plate.

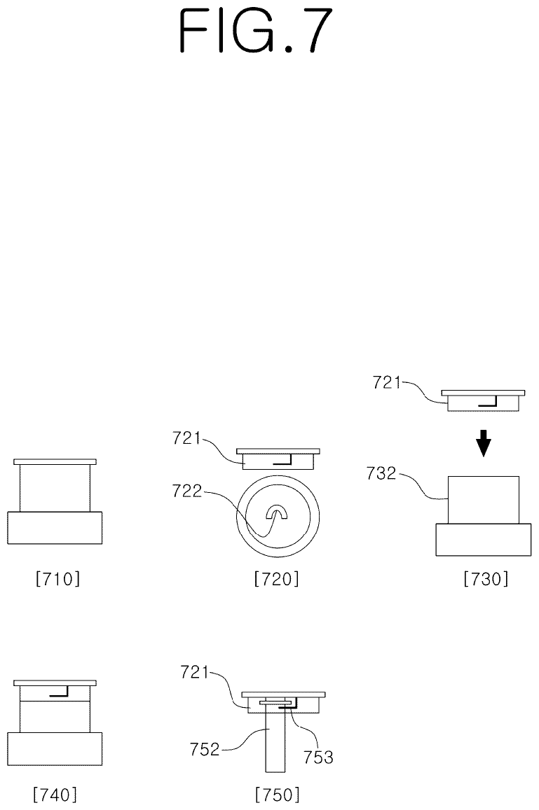

Further, FIG. 7 shows the internal structure of a notification unit according to various embodiments of the present disclosure. In accordance with various embodiments, the external appearance of the notification unit may be shown including a button member, as in [710], and in this case, the notification may be formed as in [740] by combining an upper notification unit 721 and a lower notification unit 732. Further, the notification unit may be designed such that the upper end of a solenoid core 752 positioned therein is fitted and fixed in a fixing groove 753 installed at the upper notification unit 721. The fixing groove may be shown as “722” when seen from above.

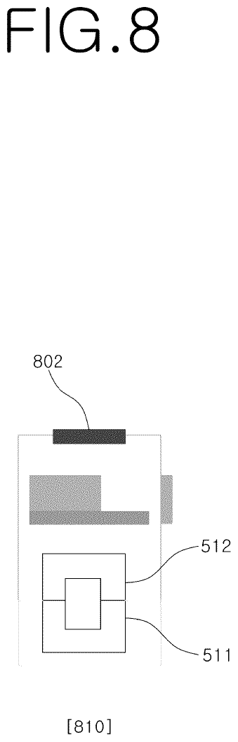

FIG. 8 shows the case in which a notification unit of a device for checking a surge according to a second embodiment of the present disclosure is implemented in a type that includes a light emission element and a circuit for driving the light emission element rather than the solenoid type. The notification unit according to the second embodiment can drive the light emission unit on the basis of an electromotive force generated in accordance with a surge current. In this case, the light emission element may be driven under the assumption that an electromotive force generated in accordance with a surge current is a threshold or more. For example, the notification unit may include a switch that is driven on the basis of a voltage/current that is a threshold or more, and can drive the light emission element under the assumption that the switch is turned on by an electromotive force that is a threshold or more.

Alternatively, the notification unit may include a display composed of a plurality of light emission elements. In this case, similarly, the plurality of light emission elements (ex, the display) can be driven under the assumption that an electromotive force generated in accordance with a surge current is a threshold or more In this case, the notification unit may be operated in the manner of displaying a count value of a surge current on the display. Further, the notification unit can initialize a count value through operation of pressing a button on a side thereof for a preset time of more. However, the present disclosure is not limited thereto and the operation of inducing initialization of the value that is displayed on the display may be set in various ways.

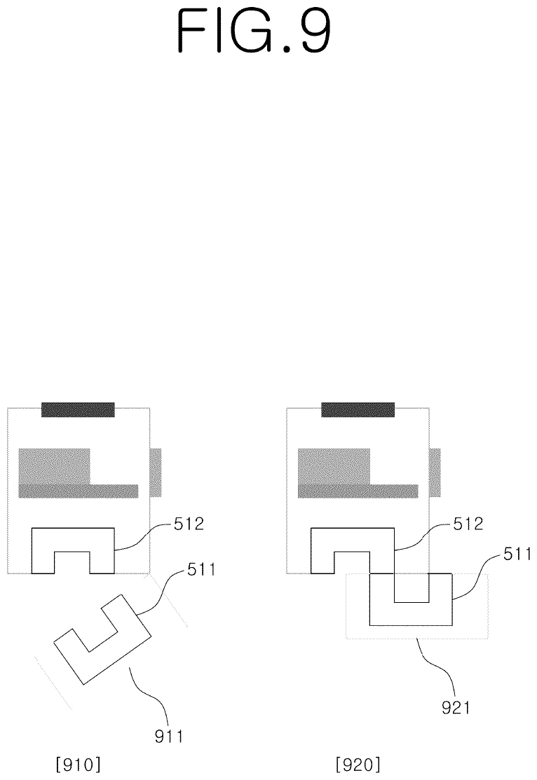

FIG. 9 shows the opening/closing types of the electromotive force generator of the device for checking a surge according to an embodiment of the present disclosure. The upper part 512 and the lower part 511 constituting the electromotive force generator can be opened by unfixing a second side with a first side fixed in accordance with operation of the hinge. However, the present disclosure is not limited thereto and it is possible to perform opening/closing operation of the upper part 512 and the lower part 511 in a sliding type. In this case, lower covers 911 and 921 each can be moved with the lower part 511 of the electromotive force generator.

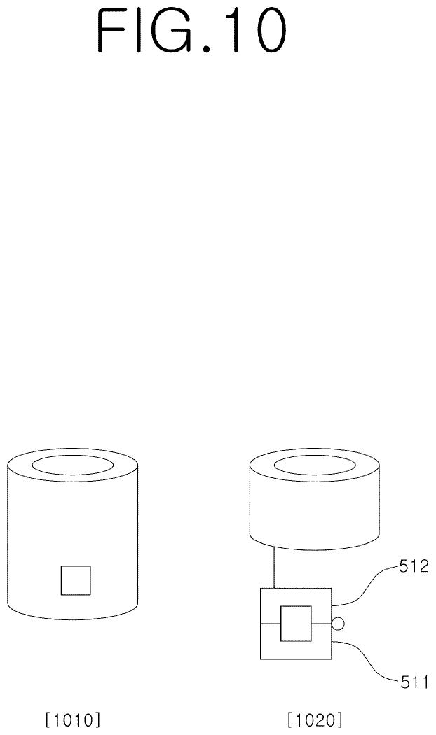

FIG. 10 shows that a device for checking a surge according to an embodiment of the present disclosure may be configured in a basic type [1010] in which the device for checking a surge has an electromotive force generator therein and an extension type [1020] in which an electromotive force generator is installed to extend.

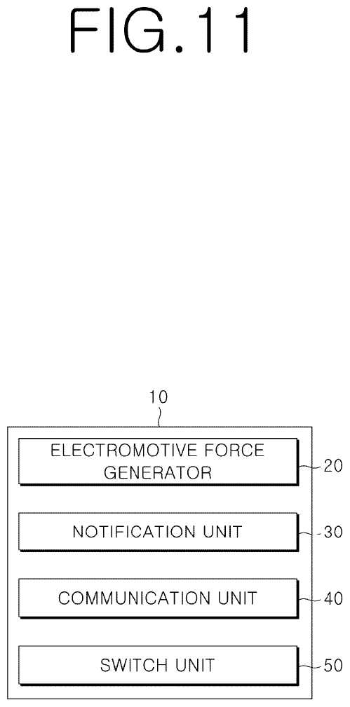

FIG. 11 shows the configuration of a device 10 for checking a surge according to an embodiment of the present disclosure. As shown in FIG. 11, the device 10 for checking a surge may include an electromotive force generator 20, a notification unit 30, a communication unit 40, and a switch unit 50.

The electromotive force generator 20 is formed to surround at least a portion of a target conducting wire at a predetermined distance from the target conducting wire and can generate an electromotive force on the basis of a surge current generated in the target conducting wire.

Further, the electromotive force generator 20 may be in a type in which a pair of U-shaped structures is fixed in a contact state to form an O-shaped hole at the center and the U-shaped structures may be ferrite cores.

Further, the electromotive force generator 20 is composed of an upper part that is a structure positioned at the upper end and a lower part that is a structure positioned at the lower end in the contact state for forming an O-shaped hole, the upper part and the lower part are connected through a hinge, and the opening/closing state can be determined in correspondence to movement of the hinge.

Further, the notification unit 30 includes a solenoid and a core formed at the center in the solenoid, and when power is supplied to the solenoid with generation of the electromotive force, the notification unit 30 can notify of generation of a surge on the basis of movement of the core. Further, the notification unit 30 includes a button member that is operated with the core formed at the center in the solenoid in contact with an end of the core, and when power is supplied to the solenoid, the core formed at the center in the solenoid protrudes and can push the button member out of the main body housing.

Further, when power is supplied to the solenoid with generation of an electromotive force and the core (solenoid core) is moved, the notification unit 30 can connect the circuit of the communication unit in correspondence to the movement of the core (solenoid core).

When the circuit is connected, the communication unit 40 can transmit information of generation of a surge to an external server.

The switch unit 50 includes an additional power supplier (a battery), and when a surge current is generated in the target conducting wire and an electromotive force is correspondingly generated, the switch unit 50 can control the additional power supplier to supply power of a preset capacity to the solenoid.

In short, a device for sensing a surge of a target conducting wire according to an embodiment of the present disclosure may include an electromotive force generator that is formed to surround at least a portion of the target conducting wire at a predetermined distance from the target conducting wire and generates an electromotive force on the basis of a surge current generated in the target conducting wire, and a notification unit that includes a solenoid and a core formed at the center in the solenoid and notifies of generation of a surge on the basis of movement of the core when power is supplied to the solenoid with generation of the electromotive force.

Further, the device for checking a surge may further include a switch unit that includes an additional power supplier and controls the additional power supplier to supply power of a preset capacity to the solenoid when a surge current is generated in the target conducting wire and an electromotive force is correspondingly generated.

Further, the device for checking a surge may further include a main body housing that accommodates the electromotive force generator and the notification unit.

Further, the notification unit includes a button member that is operated with the core formed at the center in the solenoid in contact with an end of the core, and when power is supplied to the solenoid, the core formed at the center in the solenoid protrudes and can push the button member out of the main body housing.

Further, the electromotive force generator may be configured in a type in which a pair of U-shaped structures is fixed in a contact state to form an O-shaped hole at the center.

In this case, the U-shaped structures may be ferrite cores.

Further, the electromotive force generator is composed of an upper part that is a structure positioned at the upper end and a lower part that is a structure positioned at the lower end in the contact state for forming an O-shaped hole, the upper part and the lower part are connected through a hinge, and the opening/closing state can be determined in correspondence to movement of the hinge.

Further, the device for checking a surge may further include a communication unit that transmits information of generation of a surge to an external server when a circuit is connected to a power source.

Further, when power is supplied to the solenoid with generation of the electromotive force and the core is moved, the notification unit can connect the circuit of the communication unit in correspondence to movement of the core. Accordingly, the device for checking a surge according to an embodiment of the present disclosure keeps the circuit of the communication unit disconnected when a specific surge event does not occur, thereby being able to prevent a waste of power. However, when a surge event occurs and the core is moved by operation of the solenoid, the device for checking a surge connects the circuit of the communication unit only in this situation. Accordingly, when a surge event occurs, the communication unit can transmit information of generation of the surge to an external server unlike the normal state in which a surge event does not occur.

A device for sensing a surge of a target conducting wire according to various embodiments of the present disclosure may include an electromotive force generator that is formed to surround at least a portion of the target conducting wire at a predetermined distance from the target conducting wire and generates an electromotive force on the basis of a surge current generated in the target conducting wire, and a notification unit that includes at least one light emission element and notifies of generation of a surge by driving the light emission element on the basis of the generated electromotive force. For example, when the magnitude of the electromotive force is a reference level or more, the light emission element can be driven, but the present disclosure is not limited thereto.

The present disclosure was described in detail with reference to the examples described above, but those skilled in the art may revise, change, and modify the examples without departing from the scope of the present disclosure. In short, it should be noted that the present disclosure does not have to necessarily include all of the function blocks shown in the drawings or does not have to obey all of the sequences shown in the drawings in the order shown in the drawings in order to achieve the effects intended by the present disclosure, and even if not so, it may be included in the scope of the present disclosure described in claims.

What is claimed is:

1. A device for checking a surge to sense a surge of a target conducting wire, the device comprising:
an electromotive force generator that is formed to surround at least a portion of the target conducting wire at a predetermined distance from the target conducting wire and generates an electromotive force on the basis of a surge current generated in the target conducting wire; and
a notification unit that includes a solenoid and a core formed at a center in the solenoid and notifies of generation of a surge on the basis of movement of the core when power is supplied to the solenoid with generation of the electromotive force.

2. The device of claim 1, further comprising a switch unit that includes an additional power supplier and controls the additional power supplier to supply power of a preset capacity to the solenoid when a surge current is generated in the target conducting wire and an electromotive force is correspondingly generated.

3. The device of claim 1, further comprising a main body housing that accommodates the electromotive force generator and the notification unit,
wherein the notification unit includes a button member that is operated with the core formed at the center in the solenoid in contact with an end of the core, and
when power is supplied to the solenoid, the core formed at the center in the solenoid protrudes and pushes the button member out of the main body housing.

4. The device of claim 1, wherein the electromotive force generator is configured in a type in which a pair of U-shaped structures is fixed in a contact state to form an O-shaped hole at a center.

5. The device of claim 4, wherein the U-shaped structures are ferrite cores.

6. The device of claim 4, wherein the electromotive force generator is composed of an upper part that is a structure positioned at an upper end and a lower part that is a structure positioned at a lower end in a contact state for forming an O-shaped hole, and
the upper part and the lower part are connected through a hinge, and an opening/closing state is determined in correspondence to movement of the hinge.

7. The device of claim 1, further comprising a communication unit that transmits information of generation of a surge to an external server when a circuit is connected to a power source,
wherein when power is supplied to the solenoid with generation of the electromotive force and the core is moved, the notification unit connects the circuit of the communication unit in correspondence to movement of the core.

8. A device for checking a surge to sense a surge of a target conducting wire, the device comprising:
an electromotive force generator that is formed to surround at least a portion of the target conducting wire at a predetermined distance from the target conducting wire and generates an electromotive force on the basis of a surge current generated in the target conducting wire; and
a notification unit that includes at least one light emission element and notifies of generation of a surge by driving the light emission element on the basis of the generated electromotive force.
